(19) United States
(12) Patent Application Publication
(10) Pub. No.: US 2008/0246080 A1
(43) Pub. Date: Oct. 9, 2008

(54) Shallow trench isolation (STI) based laterally diffused metal oxide semiconductor (LDMOS)

(75) Inventors: Akira Ito, Irvine, CA (US); Henry Kuo-Shun Chen, Irvine, CA (US)

Correspondence Address: STERNE, KESSLER, GOLDSTEIN & FOX P.L.L.C., 1100 NEW YORK AVENUE, N.W., WASHINGTON, DC, 20005, US

(73) Assignee: Broadcom Corporation, Irvine, CA (US)

(21) Appl. No.: 12/155,628

(22) Filed: Jun. 6, 2008

Related U.S. Application Data
(63) Continuation-in-part of application No. 11/580,961, filed on Oct. 16, 2006.
(60) Provisional application No. 60/833,787, filed on Jul. 28, 2006.

(51) Int. Cl. H01L 29/78

(52) U.S. Cl. 257/328; 257/E29.256

(57) ABSTRACT

An apparatus is disclosed to increase a breakdown voltage of a semiconductor device. The semiconductor device includes a first heavily doped region to represent a source region. A second heavily doped region represents a drain region of the semiconductor device. A third heavily doped region represents a gate region of the semiconductor device. The semiconductor device further includes a shallow trench isolation (STI) region to increase the resistance from the drain region to the source region. The STI region includes a first side vertically aligned with a second side of the gate region. The STI region extends from the first side to a second side in contact with a second side of the drain region. The breakdown voltage of the n-type semiconductor device is directly proportional to a vertical length, or a depth, of the first side and/or the second side of the STI region. The horizontal length, or distance from the first side to the second side, of the STI region does not substantially contribute to the breakdown voltage of the semiconductor device. As a result, a conventional CMOS logic foundry technology may fabricate the STI region of the semiconductor device using a low operating voltage process minimum design rule.

### CROSS REFERENCE TO RELATED APPLICATIONS

This application is a continuation in part of U.S. patent application Ser. No. 11/580,961, filed Oct. 16, 2006 which claims benefit of U.S. Provisional Application No. 60/833,787, filed Jul. 28, 2006, all of which are incorporated herein by reference in their entirety.

### FIELD OF THE INVENTION

The present invention generally relates to semiconductors. More specifically, the invention relates to increasing a breakdown voltage of a semiconductor device.

### BACKGROUND OF THE INVENTION

Silicon semiconductor processing has evolved sophisticated operations for fabricating integrated circuits. As advancement in fabrication process technology continues, the operating voltage of the integrated circuits has decreased, but the operating voltage of auxiliary devices remains the same. Auxiliary devices are devices used in conjunction with integrated circuits and may include printers, scanners, disk drives, tape drives, microphones, speakers, and cameras to provide some examples.

Auxiliary devices may operate at voltages above the breakdown voltage of the transistors contained within the integrated circuit. As the operating voltage applied to a transistor increases, the transistor will eventually breakdown allowing an uncontrollable increase in current to pass through the junction. Breakdown voltage is the voltage level where this uncontrollable increase in current occurs. Examples of breakdown may include punch-through, avalanche breakdown, and gate oxide breakdown to provide some examples. Operating above the breakdown voltage for a significant duration reduces the lifetime of the transistor.

Techniques are currently available to increase the voltage at which breakdown occurs. These techniques may include the separate design of input-output circuits using a high voltage process, double diffused drain or other extended drain techniques, or the cascading of two individual transistors to provide some examples. These techniques often increase the fabrication cost by requiring additional process steps along with additional substrate masking.

What is needed is a metal oxide semiconductor field effect transistor (MOSFET) device that addresses one or more of the aforementioned shortcomings of conventional MOSFET devices.

### BRIEF DESCRIPTION OF THE DRAWINGS/FIGURES

The accompanying drawings illustrate the present invention and, together with the description, further serve to explain the principles of the invention and to enable one skilled in the pertinent art to make and use the invention.

FIG. 1A illustrates a cross-sectional view of an n-type laterally diffused metal oxide semiconductor (LDMOS) fabricated using a conventional CMOS logic foundry technology according to an exemplary embodiment of the present invention.

FIG. 1B further illustrates the cross-sectional view of the n-type laterally diffused metal oxide semiconductor (LDMOS) fabricated using the conventional CMOS logic foundry technology according to another exemplary embodiment of the present invention.

FIG. 2A illustrates a cross-sectional view of a p-type laterally diffused metal oxide semiconductor (LDMOS) fabricated using the conventional CMOS logic foundry technology according to an exemplary embodiment of the present invention.

FIG. 2B further illustrates the cross-sectional view of the p-type laterally diffused metal oxide semiconductor (LDMOS) fabricated using the conventional CMOS logic foundry technology according to another exemplary embodiment of the present invention.

FIG. 3A illustrates a cross-sectional view of a second n-type laterally diffused metal oxide semiconductor (LDMOS) fabricated using a conventional CMOS logic foundry technology according to another exemplary embodiment of the present invention.

FIG. 3B illustrates a cross-sectional view of a drain to source resistance of the second n-type laterally diffused metal oxide semiconductor (LDMOS) according to an exemplary embodiment of the present invention.

FIG. 3C illustrates a voltage potential profile 380 from the drain region to the source region of the second n-type laterally diffused metal oxide semiconductor (LDMOS) according to an exemplary embodiment of the present invention.

FIG. 3D further illustrates the cross-sectional view of the n-type laterally diffused metal oxide semiconductor (LDMOS) fabricated using the conventional CMOS logic foundry technology according to another exemplary embodiment of the present invention.

FIG. 4A illustrates a cross-sectional view of a second p-type laterally diffused metal oxide semiconductor (LDMOS) fabricated using a conventional CMOS logic foundry technology according to another exemplary embodiment of the present invention. A conventional CMOS logic foundry technology fabricates a p-type LDMOS structure 400 onto the substrate 402 doped with the p-type material.

FIG. 4B illustrates a cross-sectional view of a drain to source resistance of the second p-type laterally diffused metal oxide semiconductor (LDMOS) according to an exemplary embodiment of the present invention.

FIG. 4C illustrates a voltage potential profile 480 from the drain region to the source region of the second p-type laterally diffused metal oxide semiconductor (LDMOS) according to an exemplary embodiment of the present invention.

FIG. 4D further illustrates the cross-sectional view of the p-type laterally diffused metal oxide semiconductor (LDMOS) fabricated using the conventional CMOS logic foundry technology according to another exemplary embodiment of the present invention.

The present invention will now be described with reference to the accompanying drawings. In the drawings, like reference numbers generally indicate identical, functionally similar, and/or structurally similar elements. The drawing in which an element first appears is indicated by the leftmost digit(s) in the reference number.

### DETAILED DESCRIPTION OF THE INVENTION

The following detailed description of the present invention refers to the accompanying drawings that illustrate exemplary embodiments consistent with this invention. Other embodiments are possible, and modifications may be made to the embodiments within the spirit and scope of the invention. Therefore, the detailed description is not meant to limit the invention. Rather, the scope of the invention is defined by the appended claims.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

Furthermore, it should be understood that spatial descriptions (e.g., “above,” “below,” “up,” “left,” “right,” “down,” “top,” “bottom,” “vertical,” “horizontal,” etc.) used herein are for purposes of illustration only, and that practical implementations of the structures described herein may be spatially arranged in any orientation or manner. Likewise, particular bit values of “0” or “1” (and representative voltage values) are used in illustrative examples provided herein to represent information for purposes of illustration only. Information described herein may be represented by either bit value (and by alternative voltage values), and embodiments described herein may be configured to operate on either bit value (and any representative voltage value), as would be understood by persons skilled in the relevant art(s).

The example embodiments described herein are provided for illustrative purposes, and are not limiting. Further structural and operational embodiments, including modifications/alterations, will become apparent to persons skilled in the relevant art(s) from the teachings herein.

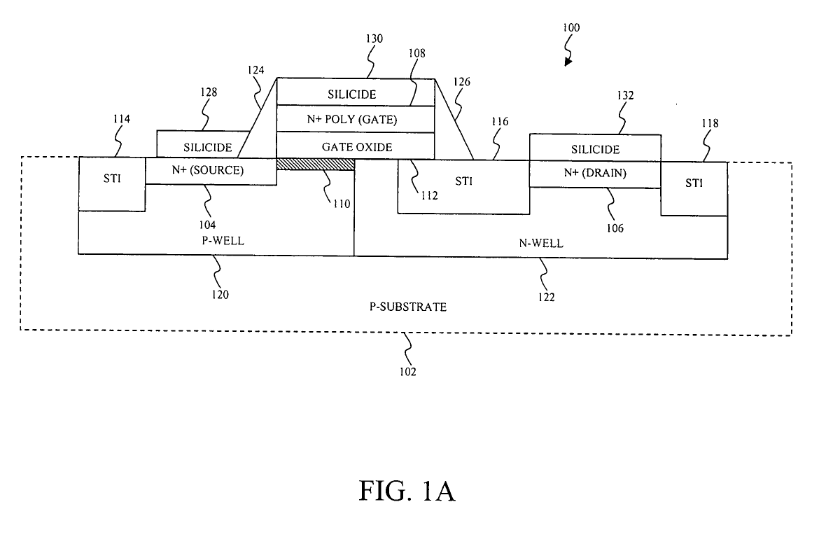

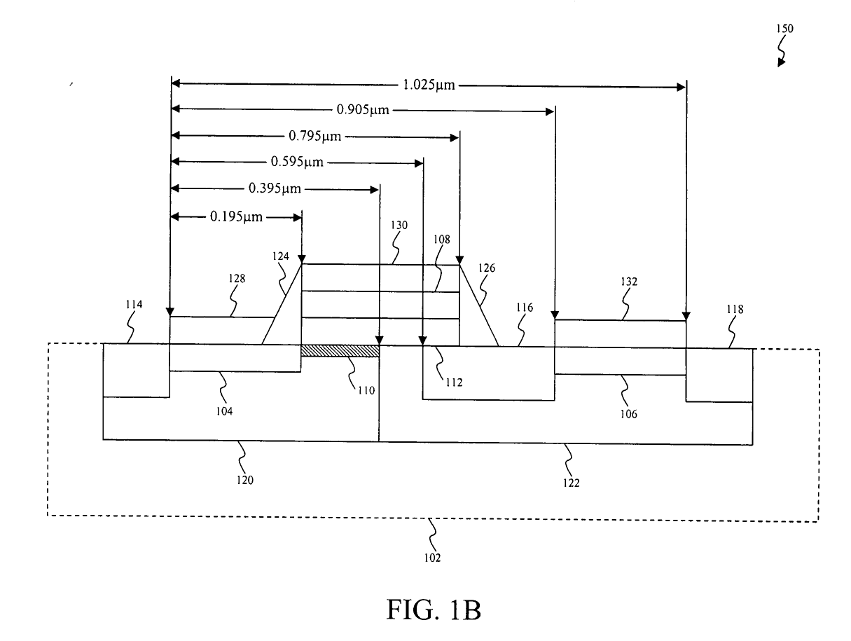

FIG. 1A illustrates a cross-sectional view of an n-type laterally diffused metal oxide semiconductor (LDMOS) fabricated using a conventional CMOS logic foundry technology according to an exemplary embodiment of the present invention. A conventional CMOS logic foundry technology fabricates an n-type LDMOS structure 100 onto a substrate 102 of one conductivity type. It should be understood that relative spatial descriptions between one or more particular features, structures, or characteristics (e.g., “vertically aligned,” “contact,” etc.) used herein are for purposes of illustration only, and that practical implementations of the structures described herein may include fabrication or misalignment tolerances of the conventional CMOS logic foundry technology without departing from the spirit and scope of the present invention. The substrate 102 represents a physical material on which conventional CMOS logic foundry technology fabricates the n-type LDMOS structure 100. For example, in the exemplary embodiment of FIG. 1A, the conventional CMOS logic foundry technology may fabricate the n-type LDMOS structure 100 onto the substrate 102 doped with a p-type material. The p-type material includes impurity atoms of an acceptor type, such as, but not limited to, boron or aluminum to provide some examples, that are capable of accepting an electron. Doping the substrate 102 with the p-type material causes a carrier hole density in the substrate 102 to exceed a carrier electron density. In other words, the carrier holes represent majority carriers, while the carrier electrons represent minority carriers in p-type materials.

A first heavily doped region of substantially opposite conductivity as the substrate 102 represents a source region 104 of the n-type LDMOS structure 100. Generally, implanting a comparatively small number of atoms, approximately

$$\frac{5 \times {10}^{18}}{{cm}^{3}} to \frac{1 \times {10}^{19}}{{cm}^{3}} ,$$

refers to an implanting that is low or light. Similarly, implanting a comparatively large number of atoms,

$$\frac{1 \times {10}^{19}}{{cm}^{3}}$$

to

$$\frac{5 \times {10}^{20}}{{cm}^{3}}$$

refers to an implanting that is high or heavy. A second heavily doped region of substantially opposite conductivity as the substrate 102 represents a drain region 106 of the n-type LDMOS structure 100. In the exemplary embodiment of FIG. 1A, the conventional CMOS logic foundry technology may implant the source region 104 and the drain region 106 with N+ material to form a first N+ region corresponding to the source region 104 and a second N+ region corresponding to the drain region 106. The n-type material includes impurity atoms of a donor type, such as, but not limited to, phosphorus, arsenic, or antimony to provide some examples, that are capable of donating an electron. Implanting the source region 104 and/or the drain region 106 with the n-type material causes the carrier electron density in the source region 104 and/or the drain region 106 to exceed a carrier hole density. In other words, the carrier electrons represent the majority carriers, while the carrier holes represent the minority carriers in n-type materials. The “+” indicates that the region is implanted with a higher carrier concentration than a region not designated by a “+.” For instance, an N+ region generally has a greater number of excess carrier electrons than an n-type region. A P+ region typically has a greater number of excess carrier holes than a p-type substrate.

A third heavily doped region of substantially opposite conductivity as the substrate 102 represents a gate region 108 of the n-type LDMOS structure 100. The gate region 108 is located between the source region 104 and the drain region 106. More specifically, a first side of the gate region 108 is substantially vertically aligned with a second side of the source region 104 and a second side of the gate region 108 is offset from the drain region 106. In other words, the second side of the gate region 108 is not substantially vertically aligned with the second side of the source region 104, rather a substantially horizontal distance separates the second side of the gate region 108 with the second side of the source region 104

The conventional CMOS logic foundry technology may heavily implant a polycrystalline silicon with the substantially opposite conductivity as the substrate 102 to form the gate region 108. In the exemplary embodiment of FIG. 1A, the conventional CMOS logic foundry technology implants the polycrystalline silicon with N+ material to form an N+ poly region corresponding to the gate region 108.

A p-n junction is a potential barrier created by combining n-type and p-type material. A first region in the substrate 102 from the substrate 102 to the source region 104 may represent a first p-n junction and a second region in the substrate 102 from the substrate 102 to the drain region 106 may represent a second p-n junction. The first p-n junction and/or the second p-n junction prevents current conduction from the source region 104 to the drain region 106 upon the application of a voltage from the source region 104 to the drain region 106. On the other hand, by applying a first potential, such as a positive direct current (DC) voltage to provide an example, to the gate region 108 and applying a second potential, such as a ground potential to provide an example, the source region 104 a voltage appears between the gate region 108 and the source region 104. A first potential voltage on the gate region 108 repels the positively charged carrier holes from a bottom side of the gate region 108 forming a channel 110. The channel 110 is a carrier-depletion region populated by a negative charge formed at a bottom side of the gate oxide 112 by an electric field. The electric field also attracts carrier electrons from the source region 104 and the drain region 106 into the channel 110. An n-type region connecting the source region 104 to the drain region 106 forms after a sufficient number of carrier electrons have accumulated in the channel 110.

The n-type LDMOS structure 100 may a part of an interconnected array of active and passive elements integrated with or deposited on the substrate 102 by a continuous series of compatible processes known as an integrated circuit. The n-type LDMOS structure 100 may include shallow trench isolation (STI) regions to provide isolation and/or protection for the n-type LDMOS structure 100 from neighboring active and passive elements integrated with or deposited on the substrate 102. An STI region 114 and an STI region 118 may provide isolation and protection for the n-type LDMOS structure 100. The STI region 114 is adjacent to a first side of the source region 104. Likewise, the STI region 118 is adjacent to a first side of the drain region 106. The STI region 114 and/or the STI region 118 may contact the respective sides of the source region 104 and/or the drain region 106. The conventional CMOS logic foundry technology may use a dielectric material such as SiO₂, though any suitable material may be used, to fabricate the STI region 114 and/or the STI region 118.

A threshold voltage of the n-type LDMOS structure 100 is a voltage at the gate region 108 at which a sufficient number of mobile electrons accumulate in channel 110 to form the channel 110. The p-type substrate used to fabricate the n-type LDMOS structure 100 contains more carrier holes as compared to carrier electrons. By applying a voltage to the gate region 108, the corresponding electric field causes the carrier electrons in the substrate to become concentrated at the region of the substrate 102 nearest the gate region 108. A depletion region forms when the concentration of carrier electrons is equal to that of the carrier holes. The n-type LDMOS structure 100 turns on when voltage applied at the gate region 108 is larger than the threshold voltage. The n-type LDMOS structure 100 turns on as a result of the number of carrier electrons exceeding carrier holes in the substrate 102 near the gate region 108. Specially implanted regions, known as wells, may increase the number of carrier holes and/or carrier electrons located in the substrate 102. For example, increasing the number of carrier holes in the substrate 102 requires a greater number of carrier electrons to form the depletion region. A specially implanted p-type region, known as a p-well 120, is adjacent to a bottom side of the source region 104, the gate region 108, and the STI region 114. The p-well 120 extends from a first side located under the STI region 114 to a second side located under the gate region 108. The conventional CMOS logic foundry technology may implant the substrate 102 with the p-type material to fabricate the p-well 120. Likewise, a specially implanted n-type region, known as an n-well 122, is located below the drain region 106, the gate region 108, and the STI region 118. The n-well 122 extends from a first side located under the STI region 118 to a second side located under the gate region 108. The conventional CMOS logic foundry technology may implant the substrate 102 with the n-type material to fabricate the n-well 122. The second side of the p-well 120 may contact the second side of the n-well 122.

The n-type LDMOS structure 100 may additionally include spacers to provide isolation and/or protection between the source region 104, the drain region 106, and/or a gate region 108. The n-type LDMOS structure 100 may include a spacer 124 between the source region 104 and the gate region 108 to isolate and/or protect the source region 104 and the gate region 108. Likewise, the n-type LDMOS structure 100 may include a spacer 126 between a top side of the drain region 106 and a second side of the gate region 108. The spacer 124 and/or the spacer 126 may contact the respective sides of the source region 104 and/or the drain region 106. The conventional CMOS logic foundry technology may fabricate the spacer 126 and/or the spacer 124 using a dielectric material, such as SiO₂, though any suitable material may be used.

A layer of silicide, an alloy of metal and silicon, forms an interconnection between the n-type LDMOS structure 100 and the other devices fabricated onto the substrate 102. The n-type LDMOS structure 100 may include a first layer of silicide 128 adjacent to the top side of the source region 104. Likewise, the n-type LDMOS structure 100 may include a second layer of silicide 130 adjacent to the top side of the gate region 108. Similarly, the n-type LDMOS structure 100 may include a third layer of silicide 132 adjacent to the top side of drain region 106. The first layer of silicide 128, the second layer of silicide 130, and/or the third layer of silicide 132 may contact the respective sides of the source region 104, the gate region 108 and/or the drain region 106.

An amount of voltage applied between the drain region 106 and the source region 104 has a limit. There is a point, known as the breakdown voltage, where the current passing through the first p-n junction and/or the second p-n junction increase uncontrollably resulting in breakdown. A breakdown voltage is the voltage at which the p-n junctions breakdown. Examples of breakdown may include avalanche breakdown, punch-through, and gate oxide breakdown to provide some examples. The point at which avalanche breakdown occurs relates to the resistance from the drain region 106 to the substrate 102. For example, a transistor with a greater drain to substrate resistance has a greater avalanche breakdown voltage than a transistor with a lesser drain to substrate resistance. This resistance decreases the influence of the electric field on the drain requiring more energy for the carriers to break covalent bonds in atoms with which they collide. As the voltage on the drain region 106 increases, the second p-n junction between the drain region 106 and the substrate 102, as described above, will eventually suffer avalanche breakdown resulting in a rapid increase in current. Avalanche breakdown results when the electric field accelerates free carrier electrons in the substrate 102 to very high speeds knocking other carrier electrons free in the substrate 102. The electric field once again accelerates both the original carrier electron and a carrier electron knocked free allowing both the carrier electron and the carrier electrons knocked free to knock more carrier electron free in the substrate 102. As this process continues, an uncontrollable increase in current occurs as a result of an exponential increase in the number of free carriers moving through the substrate 102.

As the operating voltage applied to a transistor increases, the gate to source voltage may eventually cause a breakdown of the gate oxide 112. This breakdown of the gate oxide 112, results permanent damage to the n-type LDMOS structure 100. The point at which the breakdown of the gate oxide occurs relates to the height of the gate oxide 112. For example, a transistor with a greater gate oxide height has a greater gate oxide breakdown voltage than a transistor with a lesser gate oxide height.

Punch through occurs when a voltage on the drain region 106 is increased to the point causing the depletion region of the n-well 122 surrounding the drain region 106 to extend through the channel 110 to the source region 104 causing a rapid increase in current. The point at which punch through occurs relates to a resistance from the drain region 106 to the source region 104. This resistance determines the point at which the depletion region of the n-well 122 surrounding the drain region 106 extends through the channel 110 to the source region 104. For example, a transistor with a greater drain to source resistance requires a greater voltage for punch through to occur than a transistor with a lesser drain to source resistance.

Related to punch through is the hot carrier effect. The hot carrier effect refers to the effect of high energy carrier electrons or carrier holes generated as a result of impact ionization at the channel 110. These high energy current carriers may leave the substrate 102 and tunnel into the gate oxide upon reaching a sufficiently high level of energy. For example, the main cause of the channel hot electrons effect results from the carrier electrons in the channel 110 gaining sufficient energy to leave the substrate 102 and tunneling into the gate oxide 112 causing degradation of the n-type LDMOS structure 100.

The n-type LDMOS structure 100 further includes a STI region 116 to increase the resistance from the drain region 106 to the source region 104. The increase in the resistance from the drain region 106 to the source region 104 increases the breakdown voltage of the n-type LDMOS structure 100, namely the point where the current passing through the first p-n junction and/or the second p-n junction increase uncontrollably resulting in breakdown. The STI region 116 includes a first side adjacent to a bottom side of the gate oxide 112 causing the STI region 116 to overlap the gate region 108. The STI region 116 extends from the first side to a second side in contact with a second side of the drain region 106. The conventional CMOS logic foundry technology may use a dielectric material such as SiO₂, though any suitable material may be used, to fabricate the STI region 116.

FIG. 11B further illustrates the cross-sectional view of the n-type laterally diffused metal oxide semiconductor (LDMOS) fabricated using the conventional CMOS logic foundry technology according to another exemplary embodiment of the present invention. More specifically, an LDMOS structure 150 represents an exemplary embodiment of the n-type LDMOS structure 100 fabricated using a 65 nm minimum design rule foundry technology. However, this example is not limiting, those skilled in the relevant arts will recognize that the n-type LDMOS structure 150 may be fabricated using any suitable minimum design rule foundry technology without departing from the spirit and scope of the present invention.

The conventional CMOS logic foundry technology may include minimum design rules to fabricate the n-type LDMOS structure 150 corresponding to one or more operating voltages. In other words, the conventional CMOS logic foundry technology may include a specialized set of minimum design rules, such as a first set of minimum design rules for a low operating voltage process and/or a second set of minimum design rules for a high operating voltage process to provide some examples, for a corresponding operating voltage. For example, the conventional CMOS logic foundry technology may include a first set of minimum design rules for a low operating voltage process of 1.2V, also referred to as a 1.2V process, and a high operating voltage process of 3.3V, also referred to as a 3.3V process. As another example, the conventional CMOS logic foundry technology may include a first set of minimum design rules for a low operating voltage process of 1.2V, and a high operating voltage process of 2.5V, also referred to as a 2.5V process. Typically, the low operating voltage process is used for lower power devices with thinner gate oxides when compare with the high operating voltage process. The conventional CMOS logic foundry technology fabricates the n-type LDMOS structure 150 using solely the high operating voltage process.

The conventional CMOS logic foundry technology fabricates the source region 104 of the n-type LDMOS structure 150 using the high operating voltage process. More specifically, the n-type LDMOS structure 150 fabricated using the 65 nm minimum design rule high operating voltage process includes the second side of the source region 104 fabricated at a horizontal distance of approximately 0.195 μm from the first side of the source region to form the source region 104 having a horizontal distance of approximately 0.195 μm.

The conventional CMOS logic foundry technology fabricates the p-well 120 and the n-well 122 of the n-type LDMOS structure 150 using the high operating voltage process. More specifically, the n-type LDMOS structure 150 fabricated using the 65 nm minimum design rule high operating voltage process includes the second side of the p-well 120 extending a distance of approximately 0.395 μm in a horizontal direction from the first side of the source region 104 until contacting or coming into close proximity of the n-well 122. In other words, the p-well 120, as well as the channel 110, extends a distance of approximately 0.2 μm beyond a second side of source region 104 in the horizontal direction until it contacts or comes into close proximity of the second side of the n-well 122. The second side of the p-well 120 extends a distance of approximately 0.395 μm in a horizontal direction from the first side of the source region 104 until contacting or coming into close proximity of the n-well 122. In other words, the p-well, as well as the channel 110, extends a distance of approximately 0.2 cm beyond a second side of source region 104 in the horizontal direction until it contacts or comes into close proximity of the second side of the n-well 122.

The conventional CMOS logic foundry technology fabricates the gate region 108 of the n-type LDMOS structure 150 using the high operating voltage process. More specifically, the n-type LDMOS structure 150 fabricated using the 65 nm minimum design rule high operating voltage process includes the first side of the gate region 108 at a distance of approximately 0.195 cm in the horizontal direction from the first side of the source region 104. As a result, the second side of the source region 104 is substantially vertically aligned with the first side of the gate region 108. The second side of the gate region 108 may be fabricated at a distance of approximately 0.795 μm in the horizontal direction from the first side of the source region 104. As a result, the gate region 108 overlaps the STI region 116 by a distance of approximately 0.2 μm in the horizontal direction.

The conventional CMOS logic foundry technology fabricates the drain region 106 of the n-type LDMOS structure 150 using the high operating voltage process. More specifically, the n-type LDMOS structure 150 fabricated using the 65 nm minimum design rule high operating voltage process includes the first side of the drain region 106 fabricated at a distance of approximately 1.025 μm in the horizontal direction from the first side of the source region 104. The second side of the drain region 106 may be fabricated at a distance of approximately 0.905 μm in the horizontal direction from the first side of the source region 104 to form the drain region 106 having a horizontal distance of approximately 0.12 μm.

The conventional CMOS logic foundry technology fabricates the STI region 116 of the n-type LDMOS structure 150 using the high operating voltage process. More specifically, the n-type LDMOS structure 150 fabricated using the 65 nm minimum design rule high operating voltage process includes the first side of the STI region 116 fabricated at a distance of approximately 0.595 μm in the horizontal direction from the first side of the source region 104. In other words, the n-well 122 extends a distance of approximately 0.2 μm beyond the first side of the STI region 116 in the horizontal direction until it contacts or comes into close proximity of the second side of the p-well 120. The second side of the STI region 116 may be fabricated at a distance of approximately 0.905 μm in the horizontal direction from the first side of the source region 104 resulting in a distance from the first side of the STI region 116 to the second side of the STI region 116 of approximately 0.31 μm in the horizontal direction. In addition, the second side of the drain region 106 may be fabricated at a distance of approximately 0.905 μm in the horizontal direction from the first side of the source region 104.

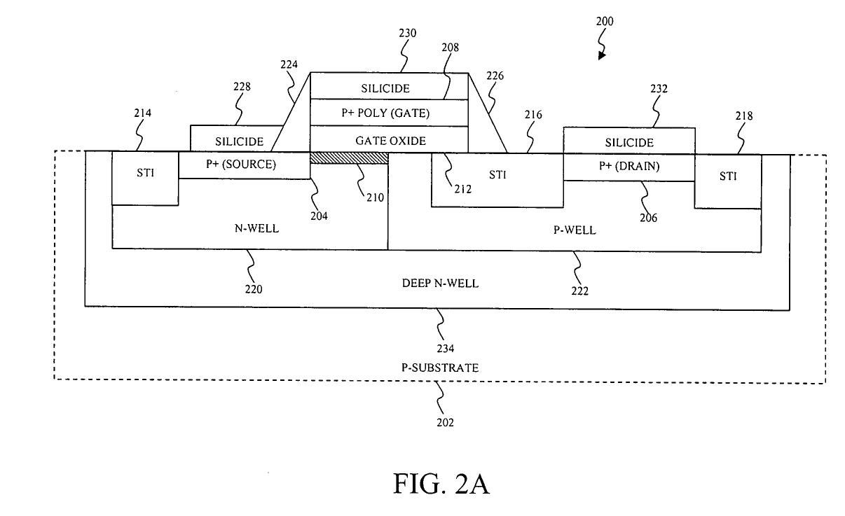

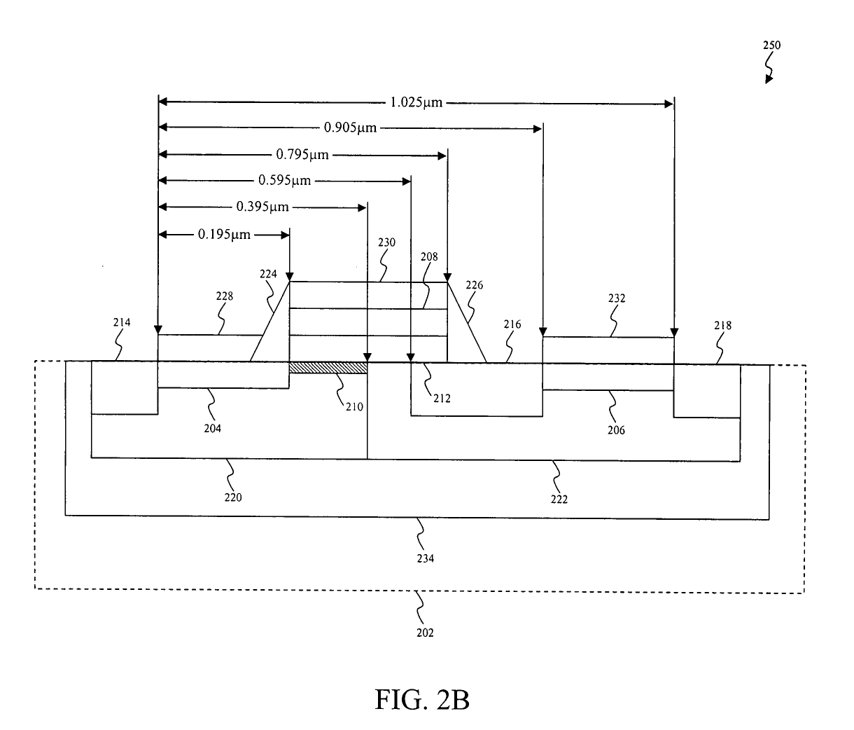

FIG. 2A illustrates a cross-sectional view of a p-type laterally diffused metal oxide semiconductor (LDMOS) fabricated using the conventional CMOS logic foundry technology according to an exemplary embodiment of the present invention. The conventional CMOS logic foundry technology fabricates a p-type LDMOS structure 200 onto a substrate 202 doped with the p-type material.

A first heavily doped region of substantially similar conductivity as the substrate 202 represents a source region 204 of the p-type LDMOS structure 200. A second heavily doped region of substantially similar conductivity as the substrate 202 represents a drain region 206 of the p-type LDMOS structure 200. In the exemplary embodiment of FIG. 2A, the conventional CMOS logic foundry technology may implant the source region 204 and the drain region 206 with P+ material to form a first P+ region corresponding to the source region 204 and a second P+ region corresponding to the drain region 206.

A third heavily doped region of substantially similar conductivity as the substrate 202 represents a gate region 208 of the p-type LDMOS structure 200. The gate region 208 is located between the source region 204 and the drain region 206. More specifically, a first side of the gate region 208 is substantially vertically aligned with a second side of the source region 204 and a second side of the gate region 208 is offset from the drain region 206. The conventional CMOS logic foundry technology may heavily implant the polycrystalline silicon with the substantially similar conductivity as the substrate 202 to form the gate region 208. In the exemplary embodiment of FIG. 2A, the conventional CMOS logic foundry technology implants the polycrystalline silicon with P+ material to form an P+ poly region corresponding to the gate region 208.

A first region in the substrate 202 from the substrate 202 to the source region 204 may represent the first p-n junction and a second region in the substrate 202 from the substrate 202 to the drain region 206 may represent the second p-n junction. The first p-n junction and/or the second p-n junction prevents current conduction from the source region 204 to the drain region 206 upon the application of a voltage from the source region 204 to the drain region 206. A first potential voltage on the gate region 208 repels the negatively charged carrier electrons from a bottom side of the gate region 208 forming a channel 210. The channel 210 is a carrier-depletion region populated by a positive charge formed at a bottom side of the gate oxide 212 by an electric field. The electric field also attracts carrier holes from the source region 204 and the drain region 206 into the channel 210. A p-type region connecting the source region 204 to the drain region 206 forms after a sufficient number of carrier holes have accumulated in the channel 210.

The STI region 214 and the STI region 218 may provide isolation and protection for the p-type LDMOS structure 200. The STI region 214 is adjacent to a first side of the source region 204. Likewise, the STI region 218 is adjacent to a first side of the drain region 206. The STI region 214 and/or the STI region 218 may contact the respective sides of the source region 204 and/or the drain region 206.

The p-type LDMOS structure 200 includes a deep n-well 234 fabricated onto the substrate 202. The n-type deep n-well 234 used to fabricate the p-type LDMOS structure 200 contains more carrier electrons as compared to carrier holes. By applying a voltage to the gate region 208, the corresponding electric field causes the carrier holes in the deep n-well 234 to become concentrated at the region of the substrate 202 nearest the gate region 208. A depletion region forms when the concentration of carrier holes is equal to that of the carrier electrons. The p-type LDMOS structure 200 turns on when voltage applied at the gate region 208 is smaller than the threshold voltage. The p-type LDMOS structure 200 turns on as a result of the number of carrier holes exceeding carrier electrons in the substrate 202 near the gate region 208. Specially implanted regions, known as wells, may increase the number of carrier holes and/or carrier electrons located in the substrate 202. For example, increasing the number of carrier holes in the substrate 202 requires a greater number of carrier electrons to form the depletion region. A specially implanted n-type region, known as an n-well 220, is adjacent to a bottom side of the source region 204, the gate region 208, and the STI region 214. The n-well 220 extends from a first side located under the STI region 214 to a second side located under the gate region 208. The conventional CMOS logic foundry technology may implant the substrate 202 with the n-type material to fabricate the n-well 220. Likewise, a specially implanted p-type region, known as a p-well 222, is located below the drain region 206, the gate region 208, and the STI region 218. The p-well 222 extends from a first side located under the STI region 218 to a second side located under the gate region 208. The conventional CMOS logic foundry technology may implant the substrate 202 with the p-type material to fabricate the p-well 222. The second side of the p-well 222 may contact the second side of the n-well 220.

The p-type LDMOS structure 200 may additionally include the spacer 224 and/or the spacer 226 to provide isolation and/or protection between the source region 204, the drain region 206, and/or a gate region 208. The p-type LDMOS structure 200 may include the first layer of silicide 228 adjacent to the top side of the source region 204. Likewise, the p-type LDMOS structure 200 may include the second layer of silicide 230 adjacent to the top side of the gate region 208. Similarly, the p-type LDMOS structure 200 may include the third layer of silicide 232 adjacent to the top side of drain region 206.

The p-type LDMOS structure 200 further includes the STI region 216 to increase the resistance from the drain region 206 to the source region 204 in a manner similar to the n-type LDMOS structure 100. The increase in the resistance from the drain region 206 to the source region 204 increases the breakdown voltage of the p-type LDMOS structure 200, namely the point where the current passing through the first p-n junction and/or the second p-n junction increase uncontrollably resulting in breakdown. The STI region 216 includes a first side adjacent to a bottom side of the gate oxide 212 causing the STI region 216 to overlap the gate region 208. The STI region 216 extends from the first side to a second side in contact with a second side of the drain region 206.

FIG. 2B further illustrates the cross-sectional view of the p-type laterally diffused metal oxide semiconductor (LDMOS) fabricated using the conventional CMOS logic foundry technology according to another exemplary embodiment of the present invention. More specifically, an LDMOS structure 250 represents an exemplary embodiment of the p-type LDMOS structure 200 fabricated using a 65 nm minimum design rule foundry technology. However, this example is not limiting, those skilled in the relevant arts will recognize that the p-type LDMOS structure 250 may be fabricated using any suitable minimum design rule foundry technology without departing from the spirit and scope of the present invention.

The conventional CMOS logic foundry technology may include minimum design rules to fabricate the p-type LDMOS structure 250 corresponding to one or more operating voltages. In other words, the conventional CMOS logic foundry technology may include a specialized set of minimum design rules, such as a first set of minimum design rules for a low operating voltage process and/or a second set of minimum design rules for a high operating voltage process to provide some examples, for a corresponding operating voltage. For example, the conventional CMOS logic foundry technology may include a first set of minimum design rules for a low operating voltage process of 1.2V, also referred to as a 1.2V process, and a high operating voltage process of 3.3V, also referred to as a 3.3V process. As another example, the conventional CMOS logic foundry technology may include a first set of minimum design rules for a low operating voltage process of 1.2V, and a high operating voltage process of 2.5V, also referred to as a 2.5V process. Typically, the low operating voltage process is used for lower power devices with thinner gate oxides when compare with the high operating voltage process. The conventional CMOS logic foundry technology fabricates the p-type LDMOS structure 250 using solely the high operating voltage process.

The conventional CMOS logic foundry technology fabricates the source region 204 of the p-type LDMOS structure 250 using the high operating voltage process. More specifically, the p-type LDMOS structure 250 fabricated using the 65 nm minimum design rule high operating voltage process includes the second side of the source region 204 fabricated at a horizontal distance of approximately 0.195 cm from the first side of the source region 204 to form the source region 204 having a horizontal distance of approximately 0.195 μm.

The conventional CMOS logic foundry technology fabricates the n-well 220 and the p-well 222 of the p-type LDMOS structure 250 using the high operating voltage process. More specifically, the p-type LDMOS structure 250 fabricated using the 65 nm minimum design rule high operating voltage process includes the second side of the n-well 220 extending a distance of approximately 0.395 μm in a horizontal direction from the first side of the source region 204 until contacting or coming into close proximity of the p-well 222. In other words, the n-well 220, as well as the channel 210, extends a distance of approximately 0.2 cm beyond a second side of source region 204 in the horizontal direction until it contacts or comes into close proximity of the second side of the p-well 222. The second side of the n-well 220 extends a distance of approximately 0.395 cm in a horizontal direction from the first side of the source region 204 until contacting or coming into close proximity of the p-well 222. In other words, the n-well 220, as well as the channel 210, extends a distance of approximately 0.2 μm beyond a second side of source region 204 in the horizontal direction until it contacts or comes into close proximity of the second side of the p-well 222.

The conventional CMOS logic foundry technology fabricates the gate region 208 of the p-type LDMOS structure 250 using the high operating voltage process. More specifically, the p-type LDMOS structure 250 fabricated using the 65 nm minimum design rule high operating voltage process includes the first side of the gate region 208 at a distance of approximately 0.195 μm in the horizontal direction from the first side of the source region 204. As a result, the second side of the source region 204 is substantially vertically aligned with the first side of the gate region 208. The second side of the gate region 208 may be fabricated at a distance of approximately 0.795 μm in the horizontal direction from the first side of the source region 204. As a result, the gate region 208 overlaps the STI region 216 by a distance of approximately 0.2 μm in the horizontal direction.

The conventional CMOS logic foundry technology fabricates the drain region 206 of the p-type LDMOS structure 250 using the high operating voltage process. More specifically, the p-type LDMOS structure 250 fabricated using the 65 nm minimum design rule high operating voltage process includes the first side of the drain region 206 fabricated at a distance of approximately 1.025 μm in the horizontal direction from the first side of the source region 204. The second side of the drain region 206 may be fabricated at a distance of approximately 0.905 μm in the horizontal direction from the first side of the source region 204 to form the drain region 206 having a horizontal distance of approximately 0.12 μm.

The conventional CMOS logic foundry technology fabricates the STI region 216 of the p-type LDMOS structure 250 using the high operating voltage process. More specifically, the p-type LDMOS structure 250 fabricated using the 65 nm minimum design rule high operating voltage process includes the first side of the STI region 216 fabricated at a distance of approximately 0.595 μm in the horizontal direction from the first side of the source region 204. In other words, the p-well 222 extends a distance of approximately 0.2 μm beyond the first side of the STI region 216 in the horizontal direction until it contacts or comes into close proximity of the second side of the n-well 220. The second side of the STI region 216 may be fabricated at a distance of approximately 0.905 μm in the horizontal direction from the first side of the source region 204 resulting in a distance from the first side of the STI region 216 to the second side of the STI region 216 of approximately 0.31 μm in the horizontal direction. In addition, the second side of the drain region 206 may be fabricated at a distance of approximately 0.905 μm in the horizontal direction from the first side of the source region 204.

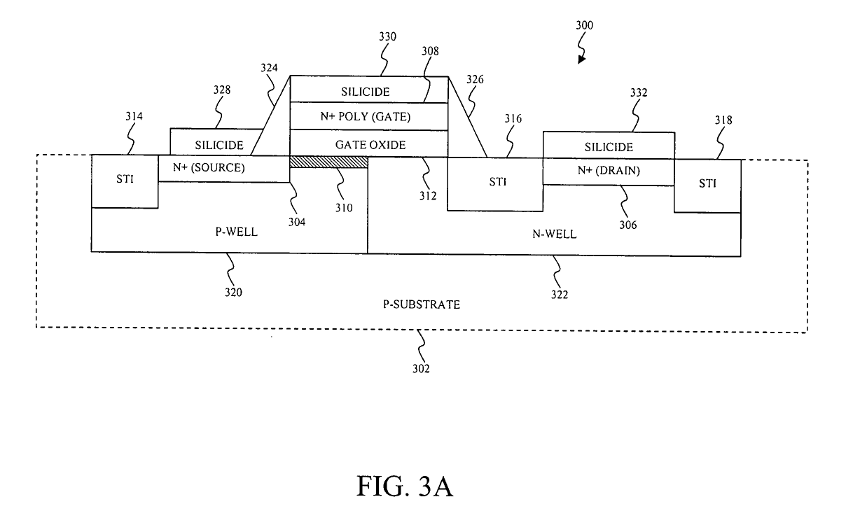

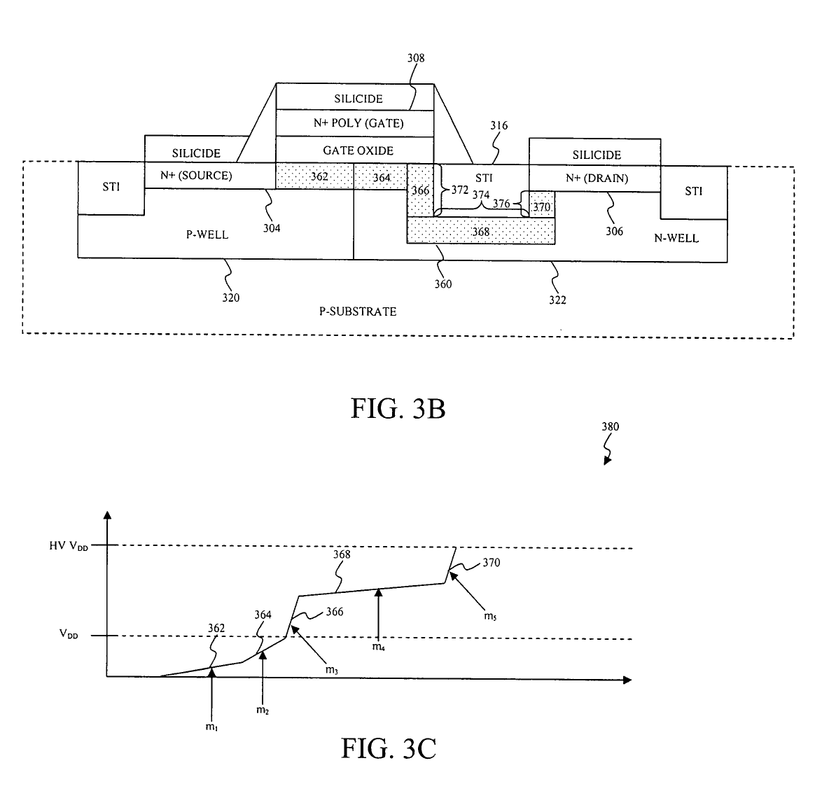

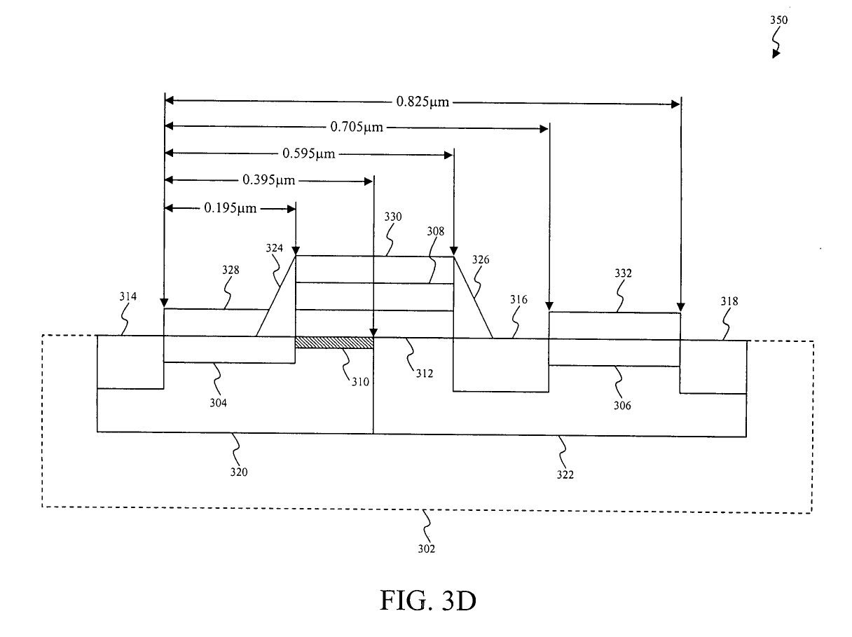

FIG. 3A illustrates a cross-sectional view of a second n-type laterally diffused metal oxide semiconductor (LDMOS) fabricated using a conventional CMOS logic foundry technology according to another exemplary embodiment of the present invention. A conventional CMOS logic foundry technology fabricates an n-type LDMOS structure 300 onto the substrate 302 doped with the p-type material.

A first heavily doped region of substantially opposite conductivity as the substrate 302 represents a source region 304 of the n-type LDMOS structure 300. A second heavily doped region of substantially opposite conductivity as the substrate 302 represents a drain region 306 of the n-type LDMOS structure 300. In the exemplary embodiment of FIG. 3A, the conventional CMOS logic foundry technology may implant the source region 304 and the drain region 306 with N+ material to form a first N+ region corresponding to the source region 304 and a second N+ region corresponding to the drain region 306.

A third heavily doped region of substantially opposite conductivity as the substrate 302 represents a gate region 308 of the n-type LDMOS structure 300. The gate region 308 is located between the source region 304 and the drain region 306. More specifically, a first side of the gate region 308 is substantially vertically aligned with a second side of the source region 304 and a second side of the gate region 308 is offset from the drain region 306. The conventional CMOS logic foundry technology may heavily implant the polycrystalline silicon with the substantially opposite conductivity as the substrate 302 to form the gate region 308. In the exemplary embodiment of FIG. 3A, the conventional CMOS logic foundry technology implants the polycrystalline silicon with N+ material to form an N+ poly region corresponding to the gate region 308.

A first region in the substrate 302 from the substrate 302 to the source region 304 may represent a first p-n junction and a second region in the substrate 302 from the substrate 302 to the drain region 306 may represent a second p-n junction. The first p-n junction and/or the second p-n junction prevents current conduction from the source region 304 to the drain region 306 upon the application of a voltage from the source region 304 to the drain region 306. A first potential voltage on the gate region 308 repels the positively charged carrier holes from a bottom side of the gate region 308 forming a channel 310. The channel 310 is a carrier-depletion region populated by a negative charge formed at a bottom side of the gate oxide 312 by an electric field. The electric field also attracts carrier electrons from the source region 304 and the drain region 306 into the channel 310. An n-type region connecting the source region 304 to the drain region 306 forms after a sufficient number of carrier electrons have accumulated in the channel 310.

The n-type LDMOS structure 300 may include an STI region 314 and an STI region 318 to provide isolation and/or protection for the n-type LDMOS structure 300 from neighboring active and passive elements integrated with or deposited on the substrate 302. The STI region 314 is adjacent to a first side of the source region 304. Likewise, the STI region 318 is adjacent to a first side of the drain region 306. The STI region 314 and/or the STI region 318 may contact the respective sides of the source region 304 and/or the drain region 306. The conventional CMOS logic foundry technology may use a dielectric material such as SiO₂, though any suitable material may be used, to fabricate the STI region 314 and/or the STI region 318.

A specially implanted p-type region, known as a p-well 320, is adjacent to a bottom side of the source region 304, the gate region 308, and the STI region 314. The p-well 320 extends from a first side located under the STI region 314 to a second side located under the gate region 308. The conventional CMOS logic foundry technology may implant the substrate 302 with the p-type material to fabricate the p-well 320. Likewise, a specially implanted n-type region, known as an n-well 322, is located below the drain region 306, the gate region 308, and the STI region 318. The n-well 322 extends from a first side located under the STI region 318 to a second side located under the gate region 308. The conventional CMOS logic foundry technology may implant the substrate 302 with the n-type material to fabricate the n-well 322. The second side of the p-well 320 may contact the second side of the n-well 322.

The n-type LDMOS structure 300 may include a spacer 326 between a top side of the drain region 306 and a second side of the gate region 308. Likewise, the n-type LDMOS structure 300 may include a spacer 324 between the source region 304 and the gate region 308 to isolate and/or protect the source region 304 and the gate region 308. The spacer 324 and/or the spacer 326 may contact the respective sides of the source region 304 and/or the drain region 306. The conventional CMOS logic foundry technology may fabricate the spacer 324 and/or the spacer 326 using a dielectric material, such as SiO₂, though any suitable material may be used.

The n-type LDMOS structure 300 may include a first layer of silicide 328 adjacent to the top side of the source region 304. Likewise, the n-type LDMOS structure 300 may include a second layer of silicide 330 adjacent to the top side of the gate region 308. Similarly, the n-type LDMOS structure 300 may include a third layer of silicide 332 adjacent to the top side of drain region 306. The first layer of silicide 328, the second layer of silicide 330, and/or the third layer of silicide 332 may contact the respective sides of the source region 304, the gate region 308 and/or the drain region 306.

The n-type LDMOS structure 300 further includes a STI region 316 to increase the resistance from the drain region 306 to the source region 304. The increase in the resistance from the drain region 306 to the source region 304 increases the breakdown voltage of the n-type LDMOS structure 300, namely the point where the current passing through the first p-n junction and/or the second p-n junction increase uncontrollably resulting in breakdown. The STI region 316 includes a first side vertically aligned with the second side of the gate region 308. The STI region 316 extends from the first side to a second side in contact with a second side of the drain region 306. The conventional CMOS logic foundry technology may use a dielectric material such as SiO₂, though any suitable material may be used, to fabricate the STI region 316.

FIG. 3B illustrates a cross-sectional view of a drain to source resistance of the second n-type laterally diffused metal oxide semiconductor (LDMOS) according to an exemplary embodiment of the present invention. From the discussion above, the STI region 316 increases a drain to source resistance 360 from the drain region 306 to the source region 304. The increase in the resistance 360 from the drain region 306 to the source region 304 of the n-type LDMOS structure 300 increases the amount of current necessary for the LDMOS structure 300 to breakdown thereby increasing the breakdown voltage of the LDMOS structure 300.

Referring back to FIG. 3B, the drain to source resistance 360 may be separated into five separate regions, wherein each region may contribute to the drain to source resistance 360. A first region 362 extends substantially horizontally from the source region 304 to the n-well 322. The first region 362 includes the channel 310 as discussed in FIG. 3A. A second region 364 extends substantially horizontally from the first region 362 to a third region 366. The third region 366 extends substantially vertically from the second region 364 to a fourth region 368 along the first side of the STI region 316. The third region 366 represents a portion of the drain to source resistance 360 resulting from a vertical length 372, or a depth, of the first side of the STI region 316. The fourth region 368 extends substantially horizontally from the third region 366 to a fifth region 370 along a bottom side of the STI region 316. The fourth region 368 represents a portion of the drain to source resistance 360 resulting from a horizontal length 374, or distance from the first side to the second side, of the STI region 316. The fifth region 370 extends substantially vertically from the fourth region 368 to a bottom side of the drain region 306 along the second side of the STI region 316. The fifth region 370 represents a portion of the drain to source resistance 360 resulting from a vertical length 376 of the second side of the STI region 316 or a difference between the depth of the STI region 316 and a depth of the drain region 306.

FIG. 3C illustrates a voltage potential profile 380 from the drain region to the source region of the second n-type laterally diffused metal oxide semiconductor (LDMOS) according to an exemplary embodiment of the present invention. As shown in FIG. 3C, the STI region 316 increases an operating voltage of the n-type LDMOS structure 300 to HV V_{DD} as compared to V_{DD} corresponding to an n-type LDMOS structure not including the STI region 316. The STI region 316 increases the breakdown voltage of n-type LDMOS structure 300 to allow the n-type LDMOS structure 300 to operate at HV V_{DD}.

The first region 362 corresponds to a voltage potential profile of the channel 310, as discussed in FIG. 3A, includes a slope of m₁. The second region 364 corresponds to a voltage potential profile from the first region 362 to the third region 366 includes a slope of m₂. The third region 366 corresponds to a voltage potential profile from the second region 364 to the fourth region 368 includes a slope of m₃. The fourth region 368 corresponds to a voltage potential profile from the third region 366 to the fifth region 370 includes a slope of m₄. The fifth region 370 corresponds to a voltage potential profile from the fourth region 368 to the drain region 306 includes a slope of m₅.

As demonstrated by FIG. 3C, the slope m₃ is substantially similar to the slope m₅ with both the slope m₃ and the slope m₅ are substantially greater than the slope m₄. As a result, the increase in breakdown voltage of the n-type LDMOS structure 300 from the STI region 316 correlates to the potential profile of the third region 366 and the potential profile of the fifth region 370. Therefore, the breakdown voltage of the n-type LDMOS structure 300 is directly proportional to the vertical length 372 of the first side and/or the vertical length 376 of the second side second side of the STI region 316. The horizontal length 374 of the STI region 316 does not substantially contribute to the breakdown voltage of the n-type LDMOS structure 300. As a result, increasing the horizontal length 374 of the STI region 316 does not substantially increase the breakdown voltage of the n-type LDMOS structure 300. However, increasing the vertical length 372 and/or the vertical length 376 of the STI region 316 does substantially increase the breakdown voltage of the n-type LDMOS structure 300.

FIG. 3D further illustrates the cross-sectional view of the n-type laterally diffused metal oxide semiconductor (LDMOS) fabricated using the conventional CMOS logic foundry technology according to another exemplary embodiment of the present invention. More specifically, an LDMOS structure 350 represents an exemplary embodiment of the n-type LDMOS structure 300 fabricated using a 65 nm minimum design rule foundry technology. However, this example is not limiting, those skilled in the relevant arts will recognize that the n-type LDMOS structure 350 may be fabricated using any suitable minimum design rule foundry technology without departing from the spirit and scope of the present invention.

Unlike the n-type LDMOS structure 100, the conventional CMOS logic foundry technology may fabricate the n-type LDMOS structure 350 using a combination of the high operating voltage process and the low operating voltage process. In other words, the n-type LDMOS structure 350, a high breakdown voltage device, may be fabricated, in part, using the minimum design rule foundry technology for the low operating voltage process. As a result, an overall horizontal distance, or size, of the n-type LDMOS structure 350 is substantially less than an overall horizontal distance, or size, of the n-type LDMOS structure 150.

The conventional CMOS logic foundry technology fabricates the source region 304 of the n-type LDMOS structure 350 using the high operating voltage process. More specifically, the n-type LDMOS structure 350 fabricated using the 65 nm minimum design rule high operating voltage process includes the second side of the source region 304 fabricated at a horizontal distance of approximately 0.195 μm from the first side of the source region 304 to form the source region 304 having a horizontal distance of approximately 0.195 μm.

The conventional CMOS logic foundry technology fabricates the p-well 320 and the n-well 322 of the n-type LDMOS structure 350 using the high operating voltage process. More specifically, the n-type LDMOS structure 350 fabricated using the 65 nm minimum design rule high operating voltage process includes the second side of the p-well 320 extending a distance of approximately 0.395 μm in a horizontal direction from the first side of the source region 304 until contacting or coming into close proximity of the n-well 322. In other words, the p-well, as well as the channel 310, extends a distance of approximately 0.2 μm beyond a second side of source region 304 in the horizontal direction until it contacts or comes into close proximity of the second side of the n-well 322. The second side of the p-well 320 extends a distance of approximately 0.395 μm in a horizontal direction from the first side of the source region 304 until contacting or coming into close proximity of the n-well 322. In other words, the p-well, as well as the channel 110, extends a distance of approximately 0.2 μm beyond a second side of source region 304 in the horizontal direction until it contacts or comes into close proximity of the second side of the n-well 322.

The conventional CMOS logic foundry technology fabricates the gate region 308 of the n-type LDMOS structure 350 using the low operating voltage process minimum design rule. More specifically, the n-type LDMOS structure 350 fabricated using the 65 nm minimum design rule low operating voltage process includes the first side of the gate region 308 at a distance of approximately 0.195 μm in the horizontal direction from the first side of the source region 304. As a result, the second side of the source region 304 is substantially vertically aligned with the first side of the gate region 308. The second side of the gate region 308 may be fabricated at a distance of approximately 0.595 μm in the horizontal direction from the first side of the source region 304. As a result, the second side of the gate region 308 is substantially vertically aligned with the first side of the STI region 316. In other words, fabricating the gate region 308 using the low operating voltage process minimum design rule substantially reduces a horizontal distance of the gate region 308 to 0.4 μm as compared to the horizontal distance of 0.6 cm for the gate region 308 fabricated using the high operating voltage process minimum design rule.

The conventional CMOS logic foundry technology fabricates the drain region 306 of the n-type LDMOS structure 350 using the high operating voltage process. More specifically, the n-type LDMOS structure 350 fabricated using the 65 nm minimum design rule high operating voltage process includes the first side of the drain region 306 fabricated at a distance of approximately 0.825 μm in the horizontal direction from the first side of the source region 304. The second side of the drain region 306 may be fabricated at a distance of approximately 0.705 μm in the horizontal direction from the first side of the source region 304 to form the drain region 306 having a horizontal distance of approximately 0.12 μm.

From the discussion above, the breakdown voltage of the n-type LDMOS structure 350 is directly proportional to the vertical length 372 and/or the vertical length 376 and substantially independent of the horizontal length 374. As a result, the conventional CMOS logic foundry technology may fabricate the STI region 316 of the n-type LDMOS structure 350 using the low operating voltage process minimum design rule. More specifically, the n-type LDMOS structure 350 fabricated using the 65 nm minimum design rule high operating voltage process includes the first side of the STI region 316 fabricated at a distance of approximately 0.595 cm in the horizontal direction from the first side of the source region 304. The second side of the STI region 316 may be fabricated at a distance of approximately 0.705 μm in the horizontal direction from the first side of the source region 304 resulting in a distance from the first side of the STI region 316 to the second side of the STI region 316 of approximately 0.11 μm in the horizontal direction.

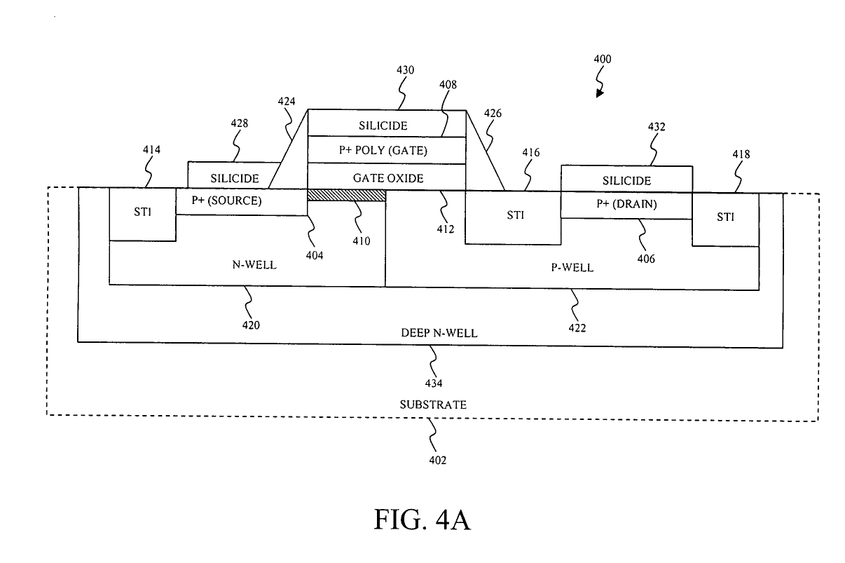

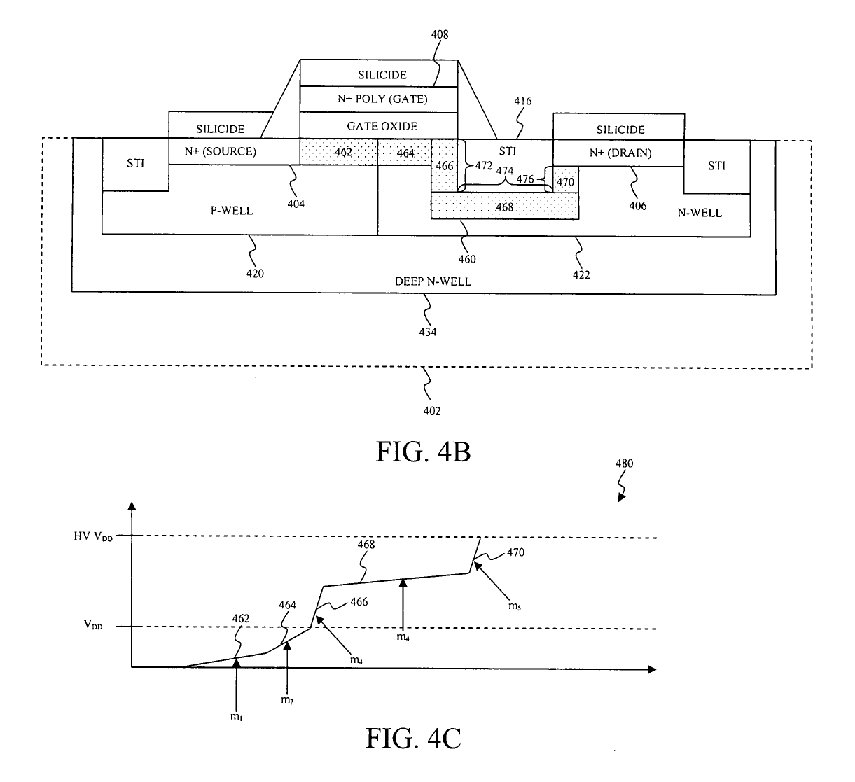

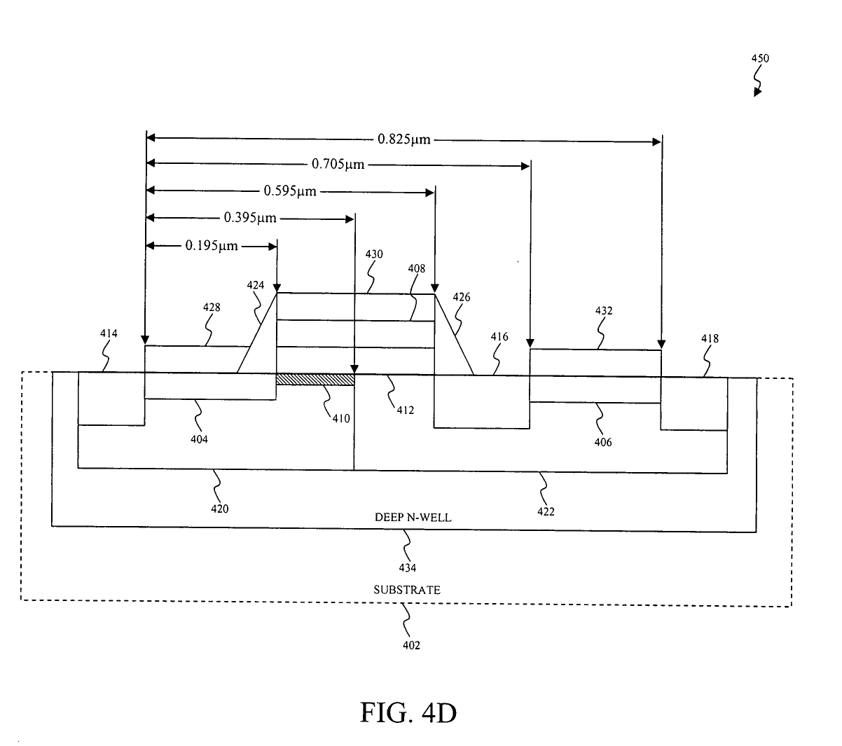

FIG. 4A illustrates a cross-sectional view of a second p-type laterally diffused metal oxide semiconductor (LDMOS) fabricated using a conventional CMOS logic foundry technology according to another exemplary embodiment of the present invention. A conventional CMOS logic foundry technology fabricates a p-type LDMOS structure 400 onto the substrate 402 doped with the p-type material.

A first heavily doped region of substantially similar conductivity as the substrate 402 represents a source region 404 of the p-type LDMOS structure 400. A second heavily doped region of substantially similar conductivity as the substrate 402 represents a drain region 406 of the p-type LDMOS structure 400. In the exemplary embodiment of FIG. 4A, the conventional CMOS logic foundry technology may implant the source region 404 and the drain region 406 with P+ material to form a first P+ region corresponding to the source region 404 and a second P+ region corresponding to the drain region 406.

A third heavily doped region of substantially similar conductivity as the substrate 402 represents a gate region 408 of the p-type LDMOS structure 400. The gate region 408 is located between the source region 404 and the drain region 406. More specifically, a first side of the gate region 408 is substantially vertically aligned with a second side of the source region 404 and a second side of the gate region 408 is offset from the drain region 406. The conventional CMOS logic foundry technology may heavily implant the polycrystalline silicon with the substantially similar conductivity as the substrate 402 to form the gate region 408. In the exemplary embodiment of FIG. 4A, the conventional CMOS logic foundry technology implants the polycrystalline silicon with P+ material to form an P+ poly region corresponding to the gate region 408.

A first region in the substrate 402 from the substrate 402 to the source region 404 may represent the first p-n junction and a second region in the substrate 402 from the substrate 402 to the drain region 406 may represent the second p-n junction. The first p-n junction and/or the second p-n junction prevents current conduction from the source region 404 to the drain region 406 upon the application of a voltage from the source region 404 to the drain region 406. A first potential voltage on the gate region 408 repels the negatively charged carrier electrons from a bottom side of the gate region 408 forming a channel 410. The channel 410 is a carrier-depletion region populated by a positive charge formed at a bottom side of the gate oxide 412 by an electric field. The electric field also attracts carrier holes from the source region 404 and the drain region 406 into the channel 410. A p-type region connecting the source region 404 to the drain region 406 forms after a sufficient number of carrier holes have accumulated in the channel 410.

The STI region 414 and the STI region 418 may provide isolation and protection for the p-type LDMOS structure 400. The STI region 414 is adjacent to a first side of the source region 404. Likewise, the STI region 418 is adjacent to a first side of the drain region 406. The STI region 414 and/or the STI region 418 may contact the respective sides of the source region 404 and/or the drain region 406.

The p-type LDMOS structure 400 includes a deep n-well 434 fabricated onto the substrate 402. The n-type deep n-well 434 used to fabricate the p-type LDMOS structure 400 contains more carrier electrons as compared to carrier holes. By applying a voltage to the gate region 408, the corresponding electric field causes the carrier holes in the deep n-well 434 to become concentrated at the region of the substrate 402 nearest the gate region 408. A depletion region forms when the concentration of carrier holes is equal to that of the carrier electrons. The p-type LDMOS structure 400 turns on when voltage applied at the gate region 408 is smaller than the threshold voltage. The p-type LDMOS structure 400 turns on as a result of the number of carrier holes exceeding carrier electrons in the substrate 402 near the gate region 408. Specially implanted regions, known as wells, may increase the number of carrier holes and/or carrier electrons located in the substrate 402. For example, increasing the number of carrier holes in the substrate 402 requires a greater number of carrier electrons to form the depletion region. A specially implanted n-type region, known as an n-well 420, is adjacent to a bottom side of the source region 404, the gate region 408, and the STI region 414. The n-well 420 extends from a first side located under the STI region 414 to a second side located under the gate region 408. The conventional CMOS logic foundry technology may implant the substrate 402 with the n-type material to fabricate the n-well 420. Likewise, a specially implanted p-type region, known as a p-well 422, is located below the drain region 406, the gate region 408, and the STI region 418. The p-well 422 extends from a first side located under the STI region 418 to a second side located under the gate region 408. The conventional CMOS logic foundry technology may implant the substrate 402 with the p-type material to fabricate the p-well 422. The second side of the n-well 420 may contact the second side of the p-well 422.

The p-type LDMOS structure 400 may additionally include the spacer 424 and/or the spacer 426 to provide isolation and/or protection between the source region 404, the drain region 406, and/or a gate region 408. The p-type LDMOS structure 400 may include the first layer of silicide 428 adjacent to the top side of the source region 404. Likewise, the p-type LDMOS structure 400 may include the second layer of silicide 430 adjacent to the top side of the gate region 408. Similarly, the p-type LDMOS structure 400 may include the third layer of silicide 432 adjacent to the top side of drain region 406.

The p-type LDMOS structure 400 further includes the STI region 416 to increase the resistance from the drain region 406 to the source region 404 in a manner similar to the n-type LDMOS structure 300. The increase in the resistance from the drain region 406 to the source region 404 increases the breakdown voltage of the p-type LDMOS structure 400, namely the point where the current passing through the first p-n junction and/or the second p-n junction increase uncontrollably resulting in breakdown. The STI region 416 includes a first side vertically aligned with the second side of the gate region 408. The STI region 416 extends from the first side to a second side in contact with a second side of the drain region 406.

FIG. 4B illustrates a cross-sectional view of a drain to source resistance of the second p-type laterally diffused metal oxide semiconductor (LDMOS) according to an exemplary embodiment of the present invention. From the discussion above, the STI region 416 increases a drain to source resistance 460 from the drain region 406 to the source region 404. The increase in the resistance 460 from the drain region 406 to the source region 404 of the p-type LDMOS structure 400 increases the amount of current necessary for the LDMOS structure 400 to breakdown thereby increasing the breakdown voltage of the LDMOS structure 400.

Referring back to FIG. 4B, the drain to source resistance 460 may be separated into five separate regions, wherein each region may contribute to the drain to source resistance 460. A first region 462 extends substantially horizontally from the source region 404 to the p-well 422. The first region 462 includes the channel 410 as discussed in FIG. 4A. A second region 464 extends substantially horizontally from the first region 462 to a third region 466. The third region 466 extends substantially vertically from the second region 464 to a fourth region 468 along the first side of the STI region 416. The third region 466 represents a portion of the drain to source resistance 460 resulting from a vertical length 472, or a depth, of the first side of the STI region 416. The fourth region 468 extends substantially horizontally from the third region 466 to a fifth region 470 along a bottom side of the STI region 416. The fourth region 468 represents a portion of the drain to source resistance 460 resulting from a horizontal length 474, or distance from the first side to the second side, of the STI region 416. The fifth region 470 extends substantially vertically from the fourth region 468 to a bottom side of the drain region 406 along the second side of the STI region 416. The fifth region 470 represents a portion of the drain to source resistance 460 resulting from a vertical length 476 of the second side of the STI region 416 or a difference between the depth of the STI region 416 and a depth of the drain region 406.

FIG. 4C illustrates a voltage potential profile 480 from the drain region to the source region of the second p-type laterally diffused metal oxide semiconductor (LDMOS) according to an exemplary embodiment of the present invention. As shown in FIG. 4C, the STI region 416 increases an operating voltage of the p-type LDMOS structure 400 to HV V_{DD} as compared to V_{DD} corresponding to a p-type LDMOS structure not including the STI region 416. The STI region 416 increases the breakdown voltage of p-type LDMOS structure 400 to allow the p-type LDMOS structure 400 to operate at HV V_{DD}.

The first region 462 corresponds to a voltage potential profile of the channel 410, as discussed in FIG. 4A, includes a slope of m₁. The second region 464 corresponds to a voltage potential profile from the first region 462 to the third region 466 includes a slope of m₂. The third region 466 corresponds to a voltage potential profile from the second region 464 to the fourth region 468 includes a slope of m₃. The fourth region 468 corresponds to a voltage potential profile from the third region 466 to the fifth region 470 includes a slope of m₄. The fifth region 470 corresponds to a voltage potential profile from the fourth region 468 to the drain region 406 includes a slope of m₅.

As demonstrated by FIG. 4C, the slope m₃ is substantially similar to the slope m₅ with both the slope m₃ and the slope m₅ being substantially greater than the slope m₄. As a result, the increase in breakdown voltage of the p-type LDMOS structure 400 from the STI region 416 correlates to the potential profile of the third region 466 and the potential profile of the fifth region 470. Therefore, the breakdown voltage of the p-type LDMOS structure 400 is directly proportional to the vertical length 472 of the first side and/or the vertical length 476 of the second side of the STI region 416. The horizontal length 474 of the STI region 416 does not substantially contribute to the breakdown voltage of the p-type LDMOS structure 400. As a result, increasing the horizontal length 474 of the STI region 416 does not substantially increase the breakdown voltage of the p-type LDMOS structure 400. However, increasing the vertical length 472 and/or the vertical length 476 of the STI region 416 does substantially increase the breakdown voltage of the p-type LDMOS structure 400.

FIG. 4D further illustrates the cross-sectional view of the p-type laterally diffused metal oxide semiconductor (LDMOS) fabricated using the conventional CMOS logic foundry technology according to another exemplary embodiment of the present invention. More specifically, an LDMOS structure 450 represents an exemplary embodiment of the p-type LDMOS structure 400 fabricated using a 65 nm minimum design rule foundry technology. However, this example is not limiting, those skilled in the relevant arts will recognize that the p-type LDMOS structure 450 may be fabricated using any suitable minimum design rule foundry technology without departing from the spirit and scope of the present invention.

Unlike the p-type LDMOS structure 200, the conventional CMOS logic foundry technology may fabricate the p-type LDMOS structure 450 using a combination of the high operating voltage process minimum design rule and the low operating voltage process minimum design rule. In other words, the p-type LDMOS structure 450, a high breakdown voltage device, may be fabricated, in part, using the minimum design rule foundry technology. As a result, an overall horizontal distance, or size, of the p-type LDMOS structure 450 is substantially less than an overall horizontal distance, or size, of the p-type LDMOS structure 250.

The conventional CMOS logic foundry technology fabricates the source region 404 of the p-type LDMOS structure 450 using the high operating voltage process. More specifically, the p-type LDMOS structure 450 fabricated using the 65 minimum design rule high operating voltage process includes the second side of the source region 404 fabricated at a horizontal distance of approximately 0.195 μm from the first side of the source region 404 to form the source region 404 having a horizontal distance of approximately 0.195 μm.

The conventional CMOS logic foundry technology fabricates the n-well 420 and the p-well 422 of the p-type LDMOS structure 450 using the high operating voltage process. More specifically, the p-type LDMOS structure 450 fabricated using the 65 nm minimum design rule high operating voltage process includes the second side of the n-well 420 extending a distance of approximately 0.395 μm in a horizontal direction from the first side of the source region 404 until contacting or coming into close proximity of the p-well 422. In other words, the n-well 420, as well as the channel 410, extends a distance of approximately 0.2 μm beyond a second side of source region 404 in the horizontal direction until it contacts or comes into close proximity of the second side of the p-well 422. The second side of the n-well 420 extends a distance of approximately 0.395 μm in a horizontal direction from the first side of the source region 404 until contacting or coming into close proximity of the p-well 422. In other words, the n-well, as well as the channel 410, extends a distance of approximately 0.2 μm beyond a second side of source region 404 in the horizontal direction until it contacts or comes into close proximity of the second side of the p-well 422.

The conventional CMOS logic foundry technology fabricates the gate region 408 of the p-type LDMOS structure 450 using the low operating voltage process minimum design rule. More specifically, the p-type LDMOS structure 450 fabricated using the 65 nm minimum design rule low operating voltage process includes the first side of the gate region 408 at a distance of approximately 0.195 μm in the horizontal direction from the first side of the source region 404. As a result, the second side of the source region 404 is substantially vertically aligned with the first side of the gate region 408. The second side of the gate region 408 may be fabricated at a distance of approximately 0.595 μm in the horizontal direction from the first side of the source region 404. As a result, the second side of the gate region 408 is substantially vertically aligned with the first side of the STI region 416. In other words, fabricating the gate region 408 using the low operating voltage process minimum design rule substantially reduces a horizontal distance of the gate region 408 to 0.4 μm as compared to the horizontal distance of 0.6 μm for the gate region 408 fabricated using the high operating voltage process minimum design rule.

The conventional CMOS logic foundry technology fabricates the drain region 406 of the p-type LDMOS structure 450 using the high operating voltage process. More specifically, the p-type LDMOS structure 450 fabricated using the 65 nm minimum design rule high operating voltage process includes the first side of the drain region 406 fabricated at a distance of approximately 0.825 μm in the horizontal direction from the first side of the source region 404. The second side of the drain region 406 may be fabricated at a distance of approximately 0.705 μm in the horizontal direction from the first side of the source region 404 to form the drain region 406 having a horizontal distance of approximately 0.12 μm.

From the discussion above, the breakdown voltage of the p-type LDMOS structure 450 is directly proportional to the vertical length 472 and/or the vertical length 476 and substantially independent of the horizontal length 474. As a result, the conventional CMOS logic foundry technology may fabricate the STI region 416 of the p-type LDMOS structure 450 using the low operating voltage process minimum design rule. More specifically, the p-type LDMOS structure 450 fabricated using the 65 nm minimum design rule high operating voltage process includes the first side of the STI region 416 fabricated at a distance of approximately 0.595 μm in the horizontal direction from the first side of the source region 404. The second side of the STI region 416 may be fabricated at a distance of approximately 0.705 μm in the horizontal direction from the first side of the source region 404 resulting in a distance from the first side of the STI region 416 to the second side of the STI region 416 of approximately 0.11 μm in the horizontal direction.

### CONCLUSION

While various embodiments of the present invention have been described above, it should be understood that they have been presented by way of example, and not limitation. It will be apparent to persons skilled in the relevant art(s) that various changes in form and detail may be made therein without departing from the spirit and scope of the invention. Thus the present invention should not be limited by any of the above-described exemplary embodiments, but should be defined only in accordance with the following claims and their equivalents.

What is claimed is:

1. A metal oxide silicon (MOS) field effect transistor device fabricated using a high operating voltage process and a low operating voltage process, comprising:
a first region forming a source region;
a second region forming a drain region;
a third region located between the source region and the drain region forming a gate region; and
a short trench isolation (STI) region, wherein the STI region includes a first side vertically aligned with the gate region, wherein at least one of the gate region and the STI region are fabricated using the low operating voltage process minimum design rule.

2. The MOS device of claim 1, wherein at least one of the source region, the drain region, and the gate region is implanted with n-type material.

3. The MOS device of claim 1, wherein at least one of the source region, the drain region, and the gate region is implanted with N+ material.

4. The MOS device of claim 1, wherein at least one of the source region, the drain region, and the gate region is implanted with p-type material.

5. The MOS device of claim 1, wherein at least one of the source region, the drain region, and the gate region is implanted with P+ material.

6. The MOS device of claim 1, further comprising:
a first well located substantially adjacent to a bottom side of the source region; and
a second well located substantially adjacent to a bottom side of the drain region, wherein the first well substantially contacts the second well adjacent to a bottom side of the gate region.

7. The MOS device of claim 6, wherein the first well is implanted with p-type material to form a p-well and the second well is implanted with n-type material to form an n-well.

8. The MOS device of claim 6, wherein the first well is implanted with n-type material to form an n-well and the second well is implanted with p-type material to form a p-well.

9. The MOS device of claim 1, wherein at least one of the gate region and the STI region are fabricated using a 65 nm minimum design rule foundry technology.

10. The MOS device of claim 1, wherein at least one of the source region and the drain region is fabricated using the high operating voltage process.

11. The MOS device of claim 1, wherein the STI region includes a distance from the first side to a second side of the STI of approximately 0.11 μm in a horizontal direction.

12. The MOS device of claim 1, wherein the gate region includes a distance from a first side to a second side of approximately 0.4 μm in a horizontal direction.

13. The MOS device of claim 1, wherein the high operating voltage process corresponds 3.3V and the low operating voltage process corresponds to 1.2V.

14. The MOS device of claim 1, wherein the high operating voltage process corresponds 2.5V and the low operating voltage process corresponds to 1.2V.

15. The MOS device of claim 1, wherein a depth of the STI region determines a breakdown voltage of the MOS device.

16. A metal oxide silicon (MOS) field effect transistor device comprising:
a first region forming a gate region;
a second region forming a drain region;
a first well located between the gate region and the drain region; and
a short trench isolation (STI) region implanted in the first well, wherein the STI region includes a first side vertically aligned with the gate region, wherein at least one of the gate region and the STI region are fabricated using a low operating voltage process minimum design rule.

17. The MOS device of claim 16, wherein at least one of the gate region, the drain region, and the first well is implanted with n-type material.

18. The MOS device of claim 16, wherein at least one of the gate region, the drain region, and the first well is implanted with p-type material.

19. The MOS device of claim 16, further comprising:
a second well located substantially adjacent to the first well, wherein the first well substantially contacts the second well adjacent to a bottom side of the gate region.

20. The MOS device of claim 16, wherein at least one of the gate region and the STI region are fabricated using a 65 nm minimum design rule foundry technology.

21. The MOS device of claim 16, wherein at least one of the source region and the drain region is fabricated using a high operating voltage process.

22. The MOS device of claim 16, wherein the STI region includes a distance from the first side to a second side of the STI of approximately 0.11 μm in a horizontal direction.

23. The MOS device of claim 16, wherein the gate region includes a distance from a first side to a second side of approximately 0.4 μm in a horizontal direction.

24. The MOS device of claim 16, wherein the low operating voltage process corresponds to 1.2V.

25. The MOS device of claim 21, wherein the high operating voltage process corresponds 3.3V.

26. The MOS device of claim 21, wherein the high operating voltage process corresponds 2.5V.

27. The MOS device of claim 16, wherein a depth of the STI region determines a breakdown voltage of the MOS device.
